(19) United States
(12) Patent Application Publication
(10) Pub. No.: US 2026/0255521 A1
(43) Pub. Date: Aug. 27, 2026

(54) PLUGIN BASED DRIVE CABINET FOR LOW VOLTAGE INDUSTRIAL APPLICATIONS DRIVE CABINET

(71) Applicant: Siemens Energy Global GmbH & Co. KG, München (DE)

(72) Inventor: Gerd Michaelis, Möhrendorf (DE)

(21) Appl. No.: 19/489,646

(22) PCT Filed: May 23, 2024
(86) PCT No.: PCT/EP2024/064173

§ 371 Date: Dec. 3, 2025

(30) Foreign Application Priority Data
Jun. 12, 2023 (GB) 2308735.6

(51) Int. Cl. H05K 7/14

(52) U.S. Cl. CPC H05K 7/14324

(57) ABSTRACT

The present invention refers to a drive cabinet plugin element providing improvements for drive cabinets. Furthermore, the present invention refers to a drive cabinet containing such drive cabinet plugin element. Additionally, the present invention refers to a method of manufacturing or servicing a drive cabinet.

### BACKGROUND

The present invention refers to a drive cabinet plugin element providing improvements for drive cabinets. Furthermore, the present invention refers to a drive cabinet containing such drive cabinet plugin element. Additionally, the present invention refers to a method of manufacturing or servicing a drive cabinet related to such drive cabinet plugin element.

Drive cabinets are essential parts of industrial applications. For example, they are required to provide a conversion of direct current to alternating current or three-phase current to power devices running on alternating current or three-phase current with a direct current power grid available at corresponding facilities. Such direct current is beneficially generated from, for example, three-phase current to provide a direct current source to be converted and provided in alternating current or three-phase current as required by the devices available in the industrial plant. Allowing to provide a tailored power grid providing, for example, a desired frequency and avoid requiring each device itself to convert the direct current.

While the generic application and utilization is well established and known, the existing systems they can still benefit from further improvements. Herein, it was noted that existing drive cabinets contain solutions to satisfy certain requirements that are already well accepted in the art as standard and not questioned anymore. However, the inventor noted that it is still possible to achieve significant improvements. For example, replacing the conversion element converting the direct current to alternating current or three-phase current is consuming a significant amount of time and effort as well as requiring intensive security measures. While such component is very reliable and only requires maintenance or replacement on a longer schedule, there is still much time and effort required in this context for each case, during which the production plant is out of operation. Furthermore, corresponding replacements parts require surprisingly highly sophisticated solutions to solve problems relating to charging the element up before going into operation mode. Resulting in a constant power consumption while such function is only required when starting up such converter again.

### SUMMARY

These problems are solved by the products as disclosed hereafter and in the claims. Further beneficial embodiments are disclosed in the dependent claims and the further description. These benefits can be used to adapt the corresponding solution to specific needs or to solve further problems.

According to one aspect, the present invention relates to a drive cabinet plugin element designed for low voltage industrial applications. The drive cabinet plugin element is configured to convert direct current into alternating current and/or three-phase current, with a preference for three-phase current. This plugin element comprises a direct current connection element, at least one converter, at least one converted current connection element, and at least one guiding element. The converter is adapted to convert direct current to alternating current and/or three-phase current, preferably three-phase current. The direct current connection element is designed to connect the drive cabinet plugin element to both a direct current source and a direct current exit. This connection element includes at least two entry contacts and at least one exit contact. Among the entry contacts, there is at least one charging entry contact and at least one operation entry contact. The charging entry contact is adapted to reduce the current flowing through it, thereby enabling the charging of the drive cabinet plugin element. The operation entry contact is adapted to allow current to flow into the drive cabinet plugin element for conversion during operation. The converted current connection element is adapted to feed the direct current, once converted into alternating current and/or three-phase current, into the drive cabinet, and to receive alternating current and/or three-phase current to be converted back into direct current. The exit contact is adapted to allow current, which has been converted from alternating current and/or three-phase current into direct current by the drive cabinet plugin element, to exit the plugin element. The guiding element is adapted to engage a rail system of a drive cabinet, which fixes the vertical location of the drive cabinet plugin element and allows for horizontal movement of the plugin element into and out of the drive cabinet. This movement, enabled by the guiding element, defines inwards and outwards locations for the plugin element. The charging entry contact is positioned inwards relative to the operation entry contact.

Typically, it is especially preferred that the at least one charging entry contact and the at least one operation entry contact provide a distance of at least 5 mm, more preferred at least 6 mm, even more preferred at least 8 mm, in direction of the movement direction into and out of the drive cabinet as enabled by the guiding element, based on the distance of first planes through the most inwards located electrical contact point of the at least one charging entry contact and being perpendicular to the movement direction and second planes through the most inwards located electrical contact point at least one operation entry contact and being perpendicular to the movement direction. The term “low voltage” as used herein has the meaning as known to the skilled person. Preferably, it refers to a supply voltage of at most 1000V AC.

It was noted that such drive cabinet plugin element provides many benefits while simultaneously even simplifying the corresponding component. While such precharging currently is typically realized by an electronically controlled charging system constantly consuming power and being possible subject to damages and/or failures requiring additional servicing the inventive drive cabinet plugin element solves this requirement simply by providing the different contacts in a specific arrangement for a redesigned drive cabinet. Wherein the redesigning of the drive cabinet simultaneously allows to further improve the safety of service persons working on it. Providing an overall improved solution being more efficient, safe and far more easy and faster to be serviced. Enabling to simply exchange a drive cabinet plugin element and its converter within minutes while the time required for such replacement before required to very often schedule corresponding service steps to ensure that no grave impact on the production at the industrial facility happens. Based on a drive cabinet malfunctioning and its big converter being required to be handled by multiple persons or even only able to be handled by machinery requiring to be replaced. While the inventive solution allows to keep some drive cabinet plugin elements in stock and even in case of malfunction a preferred version of such drive cabinet plugin element weighing at most 30 kg, even more preferred at most 20 kg, can easily be exchanged in case a malfunction is indicated.

According to a further aspect the present invention refers to a drive cabinet containing at least one inventive drive cabinet plugin element, preferably at least three inventive drive cabinet plugin elements.

According to a further aspect the present invention refers to a method of manufacturing or servicing an inventive drive cabinet, wherein an inventive drive cabinet plugin element is introduced into the drive cabinet or an inventive drive cabinet plugin element is serviced.

### BRIEF DESCRIPTION OF THE DRAWINGS

To simplify understanding of the present invention it is referred to the detailed description hereafter. Herein, the figures are to be understood being not limiting the scope of the present invention but disclosing preferred embodiments explaining the invention further.

FIG. 1 shows a schematic side view of an inventive drive cabinet.

FIG. 2 shows a schematic cross section of the drive cabinet of FIG. 1.

FIG. 3 shows an internal view of the drive cabinet of FIG. 1 containing the inventive drive cabinet plugin element showing the connection element contacting the bus bars feeding the direct current into the drive cabinet plugin element and out of the drive cabinet plugin element.

FIG. 4 shows a schematic cross section of the drive cabinet of FIG. 1 showing the bolt type fixation attaching the drive cabinet plugin element in the drive cabinet and providing a guided movement of the drive cabinet plugin element.

FIG. 5 shows a schematic representation of the three stages the drive cabinet of FIG. 1 while being guided by the bolt type fixation element of FIG. 4.

FIG. 6 shows an output reactor as contained in the specific embodiment of the drive cabinet of FIG. 1.

FIG. 7 shows the output reactor of FIG. 6 and the surrounding part of the drive cabinet including some cables within said area being connected to the output reactors.

FIG. 8 shows a schematic side view of the drive cabinet plugin element as utilized in the example depicted in FIG. 1, wherein, for example, the cover, controller and cables are not shown to allow an insight into the bottom part of the drive cabinet plugin element.

FIG. 9 shows a schematic bottom view of the drive cabinet plugin element as shown in FIG. 8 also not showing certain elements to more clearly show the guiding element and a cooling aspect.

### DETAILED DESCRIPTION

According to one aspect, the present invention refers to a drive cabinet plugin element as specified above.

According to further embodiments it is preferred that the at least two entry contacts of the direct current connection element are arranged vertically distanced from the at least one exit contact of the direct current connection element, preferably, wherein the at least two entry contacts are arranged above the at least one exit contact, based on the intended orientation of the drive cabinet plugin element in a drive cabinet. In exemplary embodiments, this apparently random placement provides significant benefits under real life conditions. Monitoring and analyzing the behavior and movements of skilled persons executing service and repairs tasks at such drive cabinet showed a significantly decreased risk of potentially interactions with an DC power source bus bar located above the corresponding bus bar utilized as exit of the DC current flowing out of the drive cabinet plugin element. Herein, this possibility to further increase the security is especially high for the solution as described herein providing. As the solution as described herein provides the possibility to significantly reduce the possible dangerous interaction points in the area containing the drive cabinet plugin element. Wherein in addition to the overall reduced number of dangerous points for a skilled person working on it, the further decreased risk of contacting the bus bar feeding the DC power to the drive cabinet plugin element surprisingly provides a significantly further improved security based on the observations and analysis in this context.

According to further embodiments it is preferred that the guiding element counterpart is a rail system. Herein, the guiding element can be, for example, corresponding rails and/or wheels enabling the directed movement as specified. Especially, combining rails limiting the direction of the drive cabinet plugin element inside the drive cabinet and wheels significantly simplifying the movement is a very efficient solution for many applications. Naturally, the skilled person is well aware of corresponding alternative solutions available to the skilled person While the skilled person is well aware of other alternatives such rail system proved to be a very reliable and efficient possibility to realize such guiding element counterpart.

According to further embodiments it is preferred that the direct current connection element comprises at least two exit elements,
wherein the at least two exit contacts comprise at least one operation exit contact and at least one discharge exit contact,
wherein the at least one operation exit contact is located inwards of the at least one discharge exit contact. Typically, it is preferred that the at least one operation exit contact and the at least one discharge exit contact provide a distance of at least 6 mm, more preferred at least 7 mm, even more preferred at least 9 mm, in direction of the movement direction into and out of the drive cabinet as enabled by the guiding element, based on the distance of third planes through the most inwards located electrical contact point of the at least one operating exit contact and being perpendicular to the movement direction and fourth planes through the most inwards located electrical contact point of the at least one discharge exit contact and being perpendicular to the movement direction.

Typically, it is especially preferred that the fourth planes provide a maximum distance from the second planes being higher than the maximum distance of the first planes from the second planes,
wherein the term maximum distance refers to the highest distance of the corresponding planes if multiple first planes, second planes and/or fourth planes are available. It was noted that the security of said drive cabinet plugin element can even further increased by including such arrangement. Herein, such arrangement allows to secure a complete discharge of the drive cabinet plugin element. While the drive cabinet plugin element can also completely covered besides the required contacts already providing a safe and secure handling even in case of remaining charge the arrangement as described above allows to provide a secure discharge.

According to further embodiments it is preferred that the drive cabinet plugin element provides a front side located on an outwards end of the drive cabinet plugin element, wherein the drive cabinet plugin element contains a status indicator on the front side of the drive cabinet. Such status indicator can be a simple LED or other light source. However, it is also possible to utilize any other means like a display. While such display enables to provide additional information and also the possibility to indicate more steps of possible problems of the drive cabinet plugin element it is not increasing the complexity of the drive cabinet plugin element as, for example, it can simply be controlled by an external controller also evaluating the state of such drive cabinet plugin element. Only requiring the corresponding wiring and a contact to engage a counter contact in the drive cabinet. However, also a simply light source like an LED blinking or lighting up is already enough to significantly improve the real-life applications. Enabling to indicate what drive cabinet plugin element is requiring to be exchanged. Naturally, such information can also be provided by outputting an information regarding the location of the required drive cabinet plugin element like third drive cabinet plugin element from the left in drive cabinet three. However, to prevent mistakes it was noted that such even very small indicator helps to prevent some small mistakes possible resulting in an emergency shutdown as the local power grid provided by such drive cabinet looses to much capacity as the incorrect drive cabinet plugin element is replaced. Also, enabling some physical inspection directly noting such indication. It was even indicated that coupling it not only with a short-term energy source, but, for example, a battery providing such lightened up light source indicator allows to prevent mistakes in case a damages drive cabinet plugin element is placed in a place also containing new or repaired drive cabinet plugin elements. During a subsequent repair of a damaged drive cabinet plugin element such status indicator can be reset again to indicate the repaired status.

According to further embodiments it is preferred that the at least one charging entry contact and the at least one operation entry contact provide a distance of at most 30 mm, more preferred at most 25 mm, even more preferred at least 15 mm, in direction of the movement direction into and out of the drive cabinet as enabled by the guiding element, based on the distance of first planes through the at least one charging entry contact and being perpendicular to the movement direction and second planes through the at least one operation entry contact and being perpendicular to the movement direction. It was noted that said distance is enough to provide a sufficient charging of the drive cabinet plugin element for typical applications. Simultaneously, it provides a very good balance taking into account the counterpart of the drive cabinet requiring a corresponding length of the direct current (DC) source enabling a compact design and further decreasing the risk of service persons coming into contact with said counterpart as it can be located remotely from the opening the drive cabinet plugin element is placed into.

According to further embodiments it is preferred that the drive cabinet plugin element provides a height h and a width w, wherein the ratio of h:w is at least 2:1, more preferred at least 3:1. The height of the drive cabinet plugin element is based on the vertical length of the drive cabinet plugin element taking into account the intended orientation of the drive cabinet plugin element in the corresponding drive cabinet. Even without the corresponding drive cabinet such intended orientation is easily available, for example, based on the at least one guiding element to allow the subsequent horizontal movement into and out of the drive cabinet. The width is to be understood accordingly. Thus, the width is the horizontal length of the drive cabinet plugin element taking into account the intended orientation of the drive cabinet plugin element in the corresponding drive cabinet. It was noted that such ratio of width and height also provides a very beneficial chimney effect which supports removal of heat losses from the power module in operation. Herein, such width is preferably determined perpendicular to the height and perpendicular to the movement direction.

According to further embodiments it is preferred that the drive cabinet plugin element provides a bolt type fixation element, wherein the bolt type fixation element provides a movement part located outside of the bolt type fixation, wherein the movement part is adapted to guide a movement of the drive cabinet plugin element when interacting with a counterpart located in a drive cabinet,
wherein the movement guided by the movement part is moving the drive cabinet plugin element into the drive cabinet or out of the drive cabinet. Typically, it is preferred that the guided movement is only a short movement. Especially, it is preferred that the movement guided by the movement part is at most 30 mm, more preferred at most 25 mm, even more preferred at most 15 mm. It was noted that even minor distance covered by such bolt type fixation is enough to provide a controlled reduced speed of the drive cabinet plugin element to pass the charging location until the operation entry contact is transferring current into the drive cabinet plugin element. Herein, even utilizing a screw type bolt type fixation element and a power tool to turn such screw already provides a sufficient delayed movement to provide the required delay. Herein, such movement can be as little like at most 20 mm, more preferred at most 15 mm to secure such controlled movement.

According to further embodiments it is preferred that the movement guided by the movement element is a continuous movement, a stepwise movement or a combination thereof. For example, such continuous movement can be achieved by a screw like movement element continuously moving the drive cabinet plugin element while the movement element engages a counterpart of the drive cabinet and the bolt type fixation element is rotated. For example, such stepwise movement can be achieved by locating elevated part of the bolt perpendicular to the axis of the bolt sliding along a guiderail of the drive cabinet counterpart of engage the bolt type fixation element, wherein the movement is stopped at least at one position. Herein, a rotation of the bolt type fixation element moves such elevated part along a guide rail surrounding the bolt type fixation element. Hereafter, the bolt type fixation element can again be moved in direction of the axis of the bolt type fixation element before either a further stop appears or the final position of the bolt and drive cabinet plugin element moving together with the bolt type fixation element is reached. Such type of bolt type fixation element resembles a multiple bayonet joint. It is also possible to combine such movement element to combine both types of movement.

According to a further aspect the present invention refers to a drive cabinet containing at least one, preferably at least three, inventive drive cabinet plugin elements.

According to further embodiments it is preferred that the drive cabinet is a drive cabinet for low voltage industrial applications. It was noted that providing a low number of drive cabinet plugin elements each providing a weight to be still easily handled by a single person and a typical cabinet size allows to provide a sufficient power distribution of typical application cases. Providing overall a surprisingly good balance to implement the present invention in existing facilities.

According to further embodiments it is preferred that the drive cabinet contains a source bus bar extending horizontally inside the drive cabinet,
wherein the drive cabinet contains at least two, preferably at least three, even more preferred at least four, drive cabinet plugin elements, wherein the source bus bar is adapted to feed direct current to the at least two drive cabinet plugin elements, wherein the at least two drive cabinet plugin elements are horizontally arranged next to each other.

According to further embodiments it is preferred that the at least one drive cabinet plugin element is located in a separated subunit of the drive cabinet, wherein the separated subunit is physically at least partially, preferably completely separated from the remaining interior of the drive cabinet. Such separated subunit is, for example, realized by surrounding the space required for the at least one drive cabinet plugin elements with walls physically separating the space of the at least one drive cabinet plugin element from the remaining interior of the drive cabinet like the at least one output reactor, wiring, and the like. The term “physically separated” preferably refers to some wall or mesh based, preferably wall based, separation of the corresponding space from the remaining part of the drive cabinet. Such separation prevents a physical interaction of, for example, a service engineer interacting with the switching cabined plugin element from physically contacting the remaining space. Typically, the at least one drive cabinet plugin element is accessible without opening the remaining interior of the drive cabinet. For example, the corresponding drive cabinet plugin elements are directly accessibly from the outside without requiring opening a door or a cover plate. Alternatively, the drive cabinet plugin elements can be covered by a door or cover plate only allowing access to the separated subunit.

It was surprisingly noted that such layout of a drive cabinet is not only possible, but simultaneously very beneficial. For example, it was noted that under real life conditions the clear delimitation of the separated subunit very efficiently prevents a contamination of the drive cabinet with dirt or fluids. Resulting from the significant weight of corresponding drive cabinet plugin elements typically still being able to be handled by a single person, however, easily leading to small mistakes ending in the drive cabinet plugin element being put on dirtied ground. Wherein corresponding contaminations are brought into the drive cabinet unless cleaned again. While the specified amended layout allows to even compensate for such mistakes and secures that a swift service of such drive cabinet can be secured.

According to further embodiments it is preferred that the at least one drive cabinet plugin element is located above at least one output reactor. This again provides some surprising benefits based on the specific design. While the drive cabinet plugin elements typically provide a high weight still being able to be handled by a single person the location of the drive cabinet plugin elements above the output reactors significantly simplifies their placement in the drive cabinet. While it was noted that the output reactors are typically providing a higher lifetime. Simultaneously, in case they are removed from the drive cabinet it is beneficially executed in a lower level as the corresponding equipment like skids utilized in this context benefit little or are even more complicated to be utilized in a higher location. Making such orientation to each other the best choice taking into account the specifics of the inventive drive cabinet plugin elements.

According to further embodiments it is preferred that the drive cabinet contains at least one output reactor, wherein the at least one output reactor provide a rail attachment,
wherein the rail attachment is fixing a vertical position of the output reactor inside the drive cabinet, wherein the rail attachment is adapted to enable the at least one output reactor to slide horizontally back and forth, preferably wherein the rail attachment is adapted to take out the output reactor from the drive cabinet when the output reactor is slid out of the drive cabinet. A corresponding design allows to very easily slide such output reactor out of the drive cabinet. Herein, it was noted that most repairs can be execute this way without requiring to completely take out such output reactor from the drive cabinet. Further significantly simplifying and improving the servicing of such output reactors.

According to further embodiments it is preferred that the cables adapted to be connected to the at least one output reactor are flexibly attached inside the drive cabinet, wherein the flexibly attached cables allow to slide the at least one output reactor along the rail attachment without the flexibly attached cables to be disconnected from the drive cabinet or the output reactor. This design feature also was surprisingly noted to be very beneficial, as especially in combination with the above specified rail attachments allows to even avoid requiring taking off the corresponding cables before a repair step of service step is carried out.

According to further embodiments it is preferred that the drive cabinet contains at least one, preferably at least three, more preferred at least four, inventive drive cabinet plugin elements,
wherein the drive cabinet is adapted to provide a contact of the at least one charging entry contact with a direct current source when the drive cabinet plugin element is moved into the drive cabinet,
wherein the drive cabinet is adapted to provide a contact of the at least one operation entry contact with a direct current source when the drive cabinet plugin element is moved further into the drive cabinet.

According to further embodiments it is preferred that the drive cabinet is a drive cabinet for low voltage industrial applications. It was noted that providing a low number of drive cabinet plugin elements each providing a weight to be still easily handled by a single person and a typical cabinet size allows to provide a sufficient power distribution of typical application cases. Providing overall a surprisingly good balance to implement the present invention in existing facilities.

According to a further aspect the present invention refers to a method of manufacturing or servicing an inventive drive cabinet, wherein an inventive drive cabinet plugin element is introduced into the drive cabinet or an inventive drive cabinet plugin element is serviced.

The following detailed description of the figure uses the figure to discuss illustrative embodiments, which are not to be construed as restrictive, along with the features and further advantages thereof.

FIG. 1 shows a schematic side view of an inventive drive cabinet 2 containing four drive cabinet plugin elements 1. One of said drive cabinet plugin elements 1 is still partially outside out of the drive cabinet 2. The four drive cabinet plugin elements 1 are adapted to convert direct current into three-phase current utilizing the converter 16 contained in each drive cabinet plugin element 1. In addition to converter 16 each drive cabinet plugin element 1 comprises a direct current connection element, a converted current connection element and two guiding elements not shown in FIG. 1 located on each side of the drive cabinet 2 elements to engage corresponding rails located in the drive cabinet 2 to fix the vertical location of the drive cabinet plugin element 1 and allowing a horizontal movement of the drive cabinet plugin element 1 into and out of the drive cabinet 2 secure the movement and location of the drive cabinet plugin elements 1 in the drive cabinet 2.

While it is essentially possible to arrange the drive cabinet plugin elements 1 in any way, it was noted that the arrangement is shown in FIG. 1 is very efficient. It also enables to increase or decrease the width of the drive cabinet 2 as required based on the power consumption within the existing facility. Allowing to easily provide tailor-made solutions based on standard components. However, it was also noted that manufacturing the drive cabinet plugin elements 1 is very efficiently realized by arranging the required components required for such drive cabinet plugin element 1 the type of layer type arrangement resulting in the shape deviating from some typical square shape. Overall resulting in the ratio of the height versus the width of the drive cabinet plugin elements 1 being around 4:1. Allowing a surprisingly efficient and reliable manufacturing of a big number of corresponding drive cabinet plugin elements 1, wherein such Drive cabinet plugin elements 1 can be easily utilized the modules to provide tailor-made solutions.

Below the drive cabinet plugin elements 1 the space of the drive cabinet 2 containing, for example, the output reactors 72 is located. FIG. 1 shows the cabinet doors 3 the output reactors 72 are located behind.

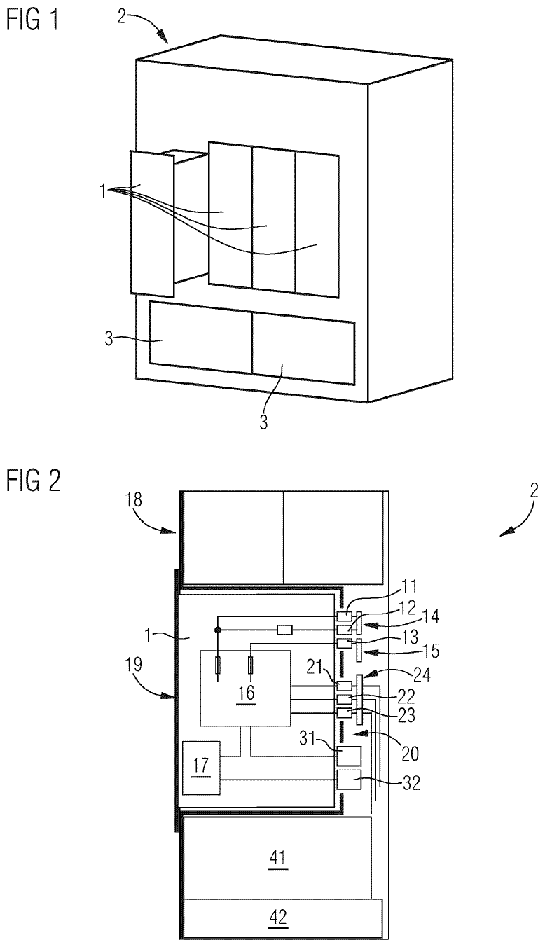

FIG. 2 shows a schematic cross section of the drive cabinet 2 of FIG. 1, wherein the contracts of a single drive cabinet 2 black and element are schematically shown. On the left the front 18 of the drive cabinet 2 is located in which the drive cabinet plugin elements 1 are placed. Herein, the front side 19 of the drive cabinet plugin elements 1 is visible even after the drive cabinet plugin elements 1 have been placed in the drive cabinet 2 The schematic cross section also shows the interior of the drive cabinet plugin element 1 containing a converter 16, a controller, as well as the electrical connections to the external contacts. The direct current connection element and converted current connection element of the drive cabinet plugin element 1 located on the backside 20 of the drive cabinet plugin element 1. Such location is typically a very useful location of such contacts for the inventive five cabinet plugin element. While it seems arbitrarily it was noted that for the inventive drive cabinet plugin element 1 providing the chance to significantly increase the overall security of the corresponding counterparts of the drive cabinet 2 this enables to further increase the security by locating the corresponding counterparts of the drive cabinet 2 also in the back section of the drive cabinet 2. While this seems counterproductive for corresponding maintenance actions the required improvement of the security based on simply keeping the contacts typically out of reach of a corresponding service person provides very efficient way to reliably improve the safety. Based on said movement an inwards and outwards location is defined.

The direct current connection element is of the drive cabinet plugin element 1 is adapted to connect the corresponding drive cabinet plugin element 1 to a direct current source and a direct current exit located inside the drive cabinet 2. Herein, the direct current connection element comprises two entry contacts and one exit contact, wherein one of the two entry contacts is a charging entry contact 12 and the other entry contact is an operation entry contact 11. The charging entry contact 12 is adapted to reduce a current flowing through the at least one charging entry contact 12 to enable a charging of the drive cabinet plugin element 1: said reduction of the direct current flowing into the drive cabinet plugin element 1 is achieved by including a resistance in the electrical connection effectively reducing the current flow in a reliable way. The operation entry contact 11 does not contain such restriction and, therefore, enables to let the direct current flow into the drive cabinet plugin element 1 to be converted during operation of the drive cabinet plugin element 1. While existing solutions provide a switching solution controlling the current flowing into an converter 16 utilized in such drive cabinet 2 the inventive solution utilizes such different contacts providing a fixed flow to very efficiently and simply provide such charging of the converter 16 without relying on complex components, which are decreasing the overall efficiency of said part of the drive cabinet 2 based on, for example, the power consumption of such components and the increased risk of failure accompanied by including more and more complex components into such parts.

To very efficiently provide a corresponding function the charging entry contact 12 is located inwards compared to the at least one operation entry contact 11. In case of the inventive example as shown in FIG. 1 the charging entry contact 12 and the operation entry contact 11 provide a distance of 7 mm in direction of the movement direction into and out of the drive cabinet 2 as enabled by the guiding element, based on the distance of first planes through the most inwards located electrical contact point of the at least one charging entry contact 12 and being perpendicular to the movement direction and second planes through the most inwards located electrical contact point at least one operation entry contact 11 and being perpendicular to the movement direction.

As indicated by the schematic drawing of FIG. 2 the at least two entry contacts of the direct current connection element are arranged vertically distanced from the at least one exit contact of the direct current connection element. In more detail the at least two entry contacts are arranged above the at least one exit contact, based on the intended orientation of the drive cabinet plugin element 1 in a drive cabinet 2.

The converted current connection element on the other hand is adapted to feed the direct current converted into three-phase current through the first phase 21, second phase 22 and third phase 23 into the three-phase current plug of the drive cabinet 2 to be further distributed by the drive cabinet 2 to the corresponding devices located in the industrial facility. The drive cabinet is located in. Herein, the converted current connection element provides an operation exit contact 11 enabling the converted three-phase current to leave the drive cabinet plugin element 1 and flow into the count elements of the cabinet.

Furthermore, the backside 20 of the drive cabinet plugin element 1 comprises contact for engaging counterparts of the drive cabinet 2. Herein, converter contact 31 is adapted to provide data with regard to the operation of the converter 16 to the converter 16. For example, such data may contain an emergency shut down signal. To improve the operation of said converter 16. Additionally, the controller as contained in the inventive example as shown in the figures receives data relevant for the operation through the controller contact 32 typically also including data with regard to the operation of the devices utilizing the three-phase current provided by the drive cabinet plugin element 1. Alternative inventive embodiments, for example, do not provide a controller in the drive cabinet plugin element 1 further simplifying the design. In case of such externalized controller the converter contact 31 receives all data required for the operation of the converter 16 and the controller contact 32 is not required. Although, a doubled wiring and a second contact 31 might be included to increase the failsafe security. Alternatively, in further embodiments not shown by the inventive example shown in the figures the converter contact is not included. In such case all data in this context is received by the controller contact and from there the converter 16 is controlled. All these embodiments have their benefits and are preferred for certain application cases. These embodiments can also be beneficially combined with the other embodiments as described in the description of the present application.

Additionally to the drive cabinet plugin element 1 the output reactor space 41 containing the output reactors 72 as well as the electric connection space 42 for the terminal 82 for electric connection are shown. As shown in the figure the drive cabinet plugin element 1 is located above the output reactors 72.

The space containing the drive cabinet plugin elements 1 represents a subunit of the drive cabinet 2 being physically separated from the remaining part of the interior of the drive cabinet 2. For this reason, corresponding wall parts physically delimiting this space are fixed into the drive cabinet 2 using bolts allowing to reduce the active parts of the drive cabinet 2 being able to be touched by someone within said space to the contacts required for the drive cabinet plugin elements 1. Naturally, such wall parts can be additionally or alternatively fixed by other means like utilizing welding or the like. Furthermore, this actively prevent dirt or moisture to enter the remaining part of the drive cabinet 2.

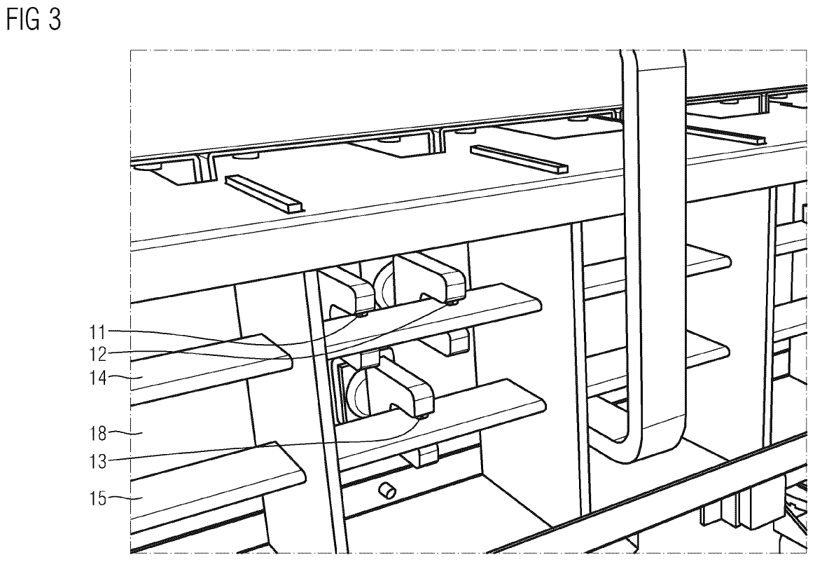

FIG. 3 shows an internal view of the drive cabinet 2 of FIG. 1 containing the inventive drive cabinet plugin element 1 showing the connection element contacting the bus bars feeding the direct current into the drive cabinet plugin element 1 and out of the drive cabinet plugin element 1.

Herein, a source bus bar 14 extending horizontally inside the drive cabinet 2. Said source bus bar 14 interacts with the two entry contacts to provide the direct current to the drive. Plugin element. As said bus bar extends horizontally through the space containing the drive cabinet plugin elements 1 all drive cabinet plugin elements 1 are contacting this bus bar.

Furthermore, an exit bus bar 15 extends in said space contacting the exit contact of the drive cabinet plugin element 1. Said exit bus bar 15 is vertically arranged below the source bus bar 14 and comparably extends horizontally through the space containing the drive cabinet plugin elements 1.

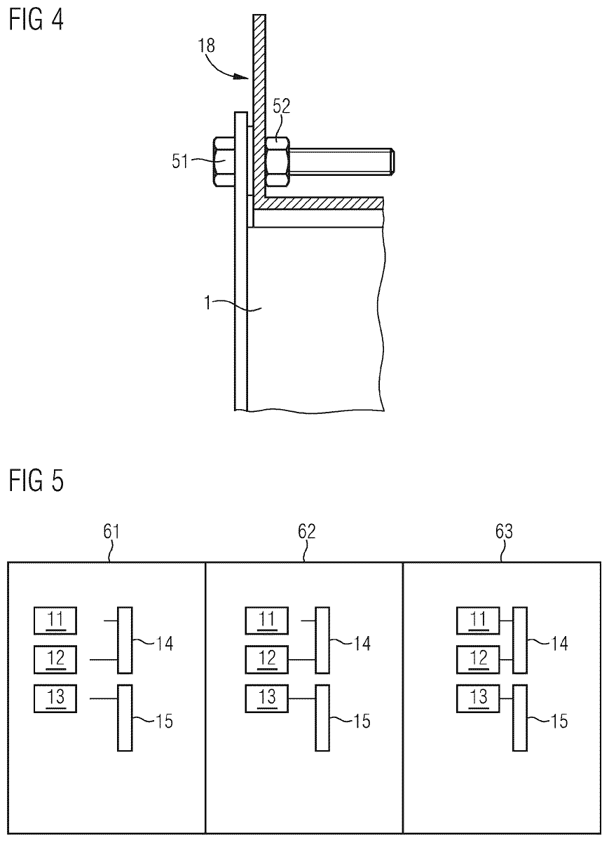

FIG. 4 shows a schematic cross section of the drive cabinet 2 of FIG. 1 showing the bolt type fixation attaching the drive cabinet plugin element 1 in the drive cabinet 2 and providing a guided movement of the drive cabinet plugin element 1. Herein, the bolt type fixation element 51 interacts with a counterpart element located in a drive cabinet 2 being a nut 52 in case of the example as shown. The nut 52 interacts with the bolt type fixation element 51 being a screw type bolt fixation element moving the drive cabinet plugin element 1 to the direction of the movement enabled by the rail system when the screw type bolt fixation element is rotated. Herein, the screw type bolt fixation elements provide a helical ridge providing a movement of the bolt type fixation element 51 and the drive cabinet plugin element 1 the bolt type fixation element 51 is in contact with while the bolt type fixation element 51 is rotated and is interacting with the counter part as comprises in the drive cabinet 2. Not explicitly shown in the figure is the attachment of the bolt type fixation elements 51 to the drive cabinet plugin element 1 fixing the relative location of the bolt type fixation elements 51 to the drive cabinet plugin element 1. Ensuring that the movement of the bolt type fixation elements 51 is directly transmitted to the drive cabinet plugin elements 1 and results in the corresponding movement of such drive cabinet plugin element 1. It was noted that even utilizing the power tool the delay originating from such screw type bolt fixation element is enough to reliably allow the converter 16 being charged based on the charging entry contact 12 first coming into contact with the direct current source of the drive cabinet 2 before the operation entry contact 11 comes into contact with such starting current source. The overall movement provided by guided by the movement part of the bolt type fixation element in this case is around 13 mm.

The example is shown in the figure provides a continuous movement of the bolt type fixation element 51 as well as the drive cabinet plugin element 1. Other embodiments not shown rely on, for example, type fixation elements containing an elongated parts including protrusions sliding along corresponding indentations of a counterpart of the drive cabinet 2. Herein, such indentation is not simply extending into one direction, but changes its orientation during the intended movements of the bolt-type fixation element requiring to rotate the bolt type fixation element to allow the protrusion of such bolt type fixation element to follow such indentation. Resulting in the bolt type fixation element 51 and the drive cabinet plugin element 1 attached thereto first being shoved into the drive until reaching such first point requiring rotating the bolt type fixation element 51. Typically, it is preferred that at such first point charging of the converter 16 takes place. The time required for rotating the bolt-type fixation element is enough for such charging to take place before the drive cabinet 2 like elements can be further moved into the drive cabinet 2 resulting in the operation entry contact 11 coming into contact with that direct current source and enabling the operation of the drive cabinet plugin element 1. Naturally, the combination of such screw type element and an alternative providing the stepwise movement as described before can be utilized. Allowing to, for example, swiftly put the five cabinet plugin elements directly into the drive cabinet 2 and moving it into a charging position, before the screw type part interacts with the counterpart, moves it into operation condition and simultaneously securely fastens the drive cabinet plugin element 1 in its operation position.

FIG. 5 shows a schematic representation of the three stages the drive cabinet 2 of FIG. 1 while being guided by the bolt type fixation element 51 of FIG. 4. Herein, a first stage 61 shows the contacting in case the corresponding drive cabinet plugin element 1 is still not in charging position. For example, in case the bolt type fixation element 51 is yet to come into contact with its counter part of the drive cabinet 2. The two entry contacts and the exit contact are not yet contacting the source bus bar 14 and exit bus bar 15.

A second stage 62 represents the contacting situation when the drive cabinet plugin element 1 is in the charging position. This state is available during rotating the bolt type fixation element 51 resulting in a continuous movement of the drive cabinet plugin element 1 to an inwards position of the drive cabinet 2. Herein the charging entry contact 12 and the exit contact are already contacting the source bus bar 14 and exit bus bar 15. However, the operation entry contact 11 is still not contacting the source bus bar 14.

A third stage 63 represents the contacting situation when the drive cabinet plugin element 1 is in the operation position. Herein, in addition to the contacts already described for the second phase the operation entry contact 11 is contacting the source bus bar 14 transmitting the direct current into the drive cabinet plugin element converting said direct current to three-phase current to be provided to the drive cabinet 2 by means of the converted current connection element.

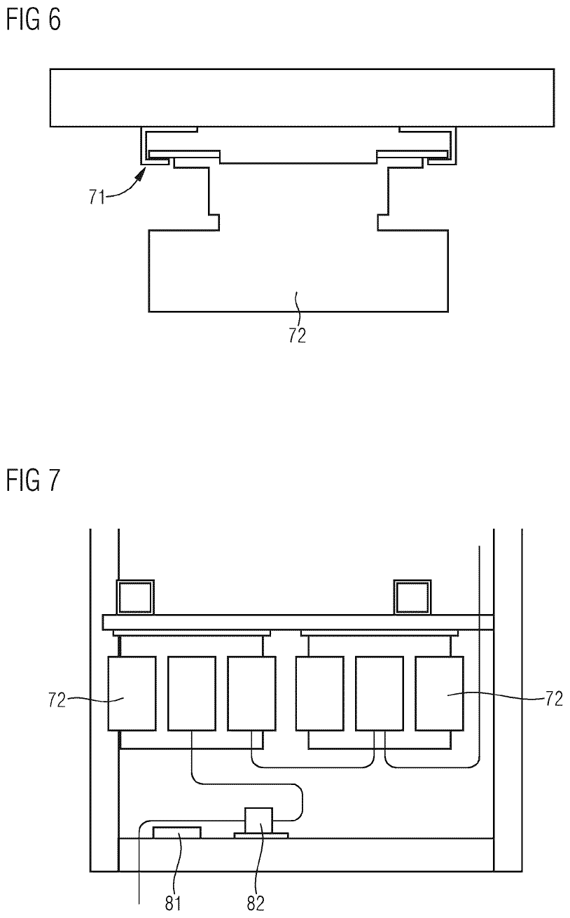

FIG. 6 shows an output reactor 72 as contained in the specific exemplarily embodiment as shown in FIG. 1. However, it needs to be emphasized that such output reactor is not necessarily included in such drive cabinet. Herein, the output reaction provides a rail attachment interacting with a rail system 71 of the drive cabinet 2. The rail attachment is fixing a vertical position of the output reactor 72 inside the drive cabinet 2. Furthermore, the rail attachment is adapted to enable the output reactors 72 to slide horizontally back and forth along the rail system 71. Herein, the output reactors 72 can be taken out from the drive cabinet 2 when the output reactor 72 is slid out of the drive cabinet 2.

FIG. 7 shows the output reactor 72 of FIG. 6 and the surrounding part of the drive cabinet 2 including some cables within said area being connected to the output reactors 72. Herein, the cables are flexibly attached allowing the movement of the output reactors 72 along the rail system 71 without requiring detaching these cables from the drive cabinet 2 or the output reactors 72.

Additionally, FIG. 7 shows some terminal 82 terminals 82 and a PE busbar 81 81 located at the bottom of the drive cabinet 2. Corresponding terminal 82 terminals for electrical connection can be easily located at the bottom of the drive cabinet 2, for example, without physically delimiting for the space containing the output reactors 72 72. Allowing to easily access them as required. For example, to inspect them during maintenance of the output reactors 72 72.

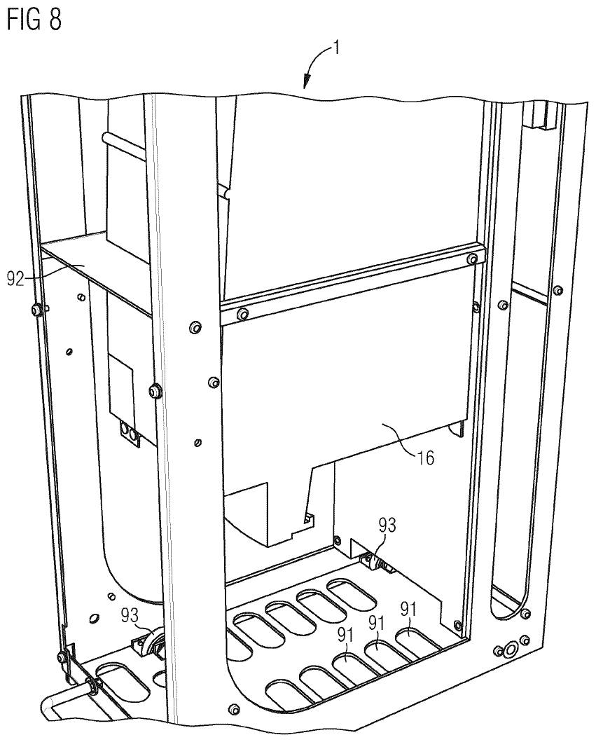

FIG. 8 shows a schematic side view of the drive cabinet plugin element 1 as utilized in the example depicted in FIG. 1, wherein, for example, the cover, controller 17 and cables are not shown to allow an insight into the bottom part of the drive cabinet plugin element 1. Herein, the openings 91 are clearly visible. However, only the reference number has only be assigned for three openings 91 to simplify the figure. The openings 91 enable an air flow from the bottom to the top of the drive cabinet plugin element 1. Herein, the drive cabinet plugin element furthermore contains a sealing plate 92 located inside and in the middle part of the drive cabinet plugin element 1. Said sealing plate 92 essentially prevent air to flow around the converter 16 of the drive cabinet plugin element 1, but forces said air to flow through the converter 16. Providing in combination with the aspect ratio of the height and width a very simply yet surprisingly efficient cooling of said converter 16. Additionally, FIG. 8 shows two wheels 93 of the guiding element 94.

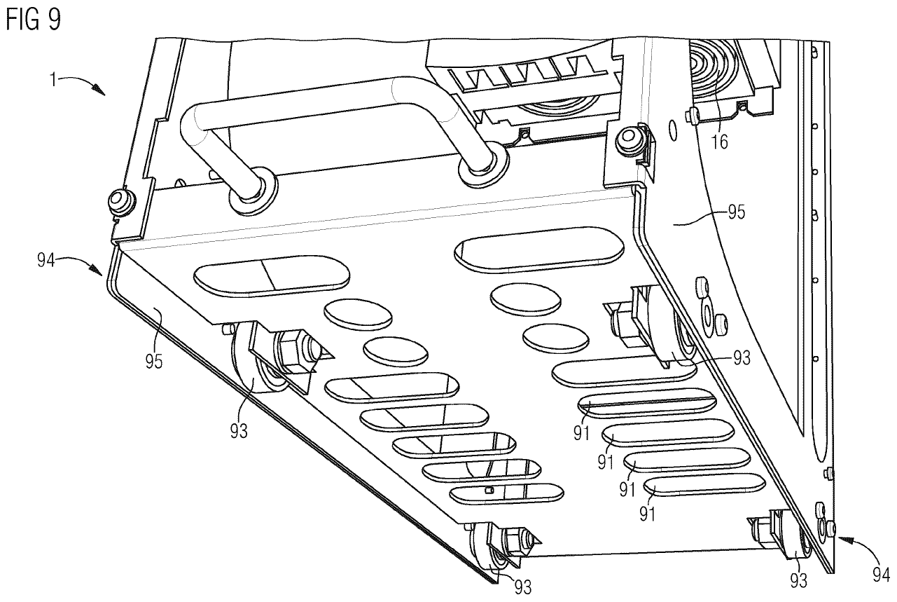

FIG. 9 shows a schematic bottom view of the drive cabinet plugin element 1 as shown in FIG. 8 also not showing certain elements to more clearly show the guiding element 94 and further illustrating the cooling aspect already described above. Herein, the four wheels 93 significantly simplify the movement of the drive cabinet plugin element 1 into and out of the drive cabinet. Simultaneously, the rail system 95 containing one rail left of the wheels 93 and one rail right of the wheels 93 restricts the movement of the drive cabinet plugin element 1 when it is moved into and out of the drive cabinet. Overall providing a very reliable guiding element 94 consisting of the rail system 95 and the wheels 93 significantly reducing the required effort to correctly place the drive cabinet plugin element 1 in the drive cabinet 2 directly guiding the drive cabinet plugin element 1 to the correct position and securing the correct contacting of the contacts without further effort.

Furthermore, the schematic bottom view shows the openings 91 located at the bottom of the drive cabinet plugin element 1 allowing the air to efficiently cool the converter 16. Again, the reference number is only assigned to a limited number of openings 91 to simplify the figure. Additionally, openings of the converter 16 are visible allowing the air entering the drive cabinet plugin element 1 through the openings 91 to flow through the converter 16 very efficiently cooling down said converter 16.

The present invention was only described in further detail for explanatory purposes. However, the invention is not to be understood being limited to these embodiments as they represent embodiments providing benefits to solve specific problems or fulfilling specific needs. The scope of the protection should be understood to be only limited by the claims attached.

1. A drive cabinet plugin element for low voltage industrial applications, the drive cabinet plugin element comprising:
a converter adapted to convert direct current into alternating current and/or three-phase current;
a direct current connection element adapted to connect the drive cabinet plugin element to a direct current source and a direct current exit, the direct current connection element comprising at least two entry contacts and at least one exit contact, the at least two entry contacts comprising at least one charging entry contact and at least one operation entry contact, the at least one charging entry contact being adapted to reduce a current flowing through the at least one charging entry contact to enable charging of the drive cabinet plugin element, the at least one operation entry contact being adapted to allow a current to flow into the drive cabinet plugin element to be converted during operation;
at least one converted current connection element adapted to feed direct current converted into alternating current and/or three-phase current into the drive cabinet and to receive alternating current and/or three-phase current to be converted into direct current;
the at least one exit contact being adapted to allow a current converted from alternating current and/or three-phase current into direct current by the drive cabinet plugin element to leave the drive cabinet plugin element; and
at least one guiding element adapted to engage a guiding element counterpart of a drive cabinet, the at least one guiding element fixing a vertical position of the drive cabinet plugin element inside the drive cabinet and enabling horizontal movement of the drive cabinet plugin element into and out of the drive cabinet, wherein such movement enabled by the at least one guiding element provides a movement direction into and out of the drive cabinet, wherein based on the enabled movement, inwards and outwards locations are defined, and wherein the at least one charging entry contact is located inwards compared to the at least one operation entry contact.

2. The drive cabinet plugin element according to claim 1, wherein the at least two entry contacts of the direct current connection element are arranged vertically distanced from the at least one exit contact of the direct current connection element.

3. The drive cabinet plugin element according to claim 1, wherein direct current connection element comprises at least two exit elements,
wherein the at least two exit contacts comprise at least one operation exit contact and at least one discharge exit contact,
wherein the at least one operation exit contact is located inwards of the at least one discharge exit contact

4. The drive cabinet plugin element according to claim 1, wherein the at least one charging entry contact and the at least one operation entry contact provide a distance of at most 30 mm in direction of the movement direction into and out of the drive cabinet as enabled by the guiding element, based on the distance of first planes through the at least one charging entry contact and being perpendicular to the movement direction and second planes through the at least one operation entry contact and being perpendicular to the movement direction.

5. The drive cabinet plugin element according to claim 1, wherein the drive cabinet plugin element provides a height h and a width w,
wherein a ratio of h:w is at least 2:1.

6. The drive cabinet plugin element according to claim 1,
wherein the drive cabinet plugin element provides a bolt type fixation element, wherein the bolt type fixation element provides a movement part located outside of the bolt type fixation,
wherein the movement part is adapted to guide a movement of the drive cabinet plugin element when interacting with a counterpart located in a drive cabinet,
wherein the movement guided by the movement part is moving the drive cabinet plugin element into the drive cabinet or out of the drive cabinet,
wherein the movement guided by the movement part is at most 20 mm.

7. The drive cabinet plugin element according to claim 6, wherein the movement guided by the movement element is a continuous movement, a stepwise movement or a combination thereof.

8. A drive cabinet containing at least one drive cabinet plugin elements according to claim 1.

9. The drive cabinet according to claim 8, wherein the drive cabinet is a drive cabinet for low voltage industrial applications.

10. The drive cabinet according to claim 8, wherein the drive cabinet contains a source bus bar extending horizontally inside the drive cabinet,
wherein the drive cabinet contains at least two drive cabinet plugin elements,
wherein the source bus bar is adapted to feed direct current to the at least two drive cabinet plugin elements,
wherein the at least two drive cabinet plugin elements are horizontally arranged next to each other.

11. The drive cabinet according to claim 8, wherein the at least one drive cabinet plugin element is located in a separated subunit of the drive cabinet,
wherein the separated subunit is physically at least partially separated from the remaining interior of the drive cabinet.

12. The drive cabinet according to claim 8, wherein the at least one drive cabinet plugin element is located above at least one output reactor.

13. The drive cabinet according to claim 12, wherein the drive cabinet contains at least one output reactor,
wherein the at least one output reactor provide a rail attachment,
wherein the rail attachment is fixing a vertical position of the output reactor inside the drive cabinet, wherein the rail attachment is adapted to enable the at least one output reactor to slide horizontally back and forth, and
wherein the rail attachment is adapted to take out the output reactor from the drive cabinet when the output reactor is slid out of the drive cabinet.

14. The drive cabinet according to claim 13, wherein cables adapted to be connected to the at least one output reactor are flexibly attached inside the drive cabinet, wherein the cables allow to slide the at least one output reactor along the rail attachment without the cables to be disconnected from the drive cabinet or the output reactor.

15. A method of manufacturing a drive cabinet, the method comprising:
introducing a drive cabinet plugin element into the drive cabinet, wherein the drive cabinet plugin element comprises:
a converter adapted to convert direct current into alternating current and/or three-phase current;
a direct current connection element adapted to connect the drive cabinet plugin element to a direct current source and a direct current exit, the direct current connection element comprising at least two entry contacts and at least one exit contact, the at least two entry contacts comprising at least one charging entry contact and at least one operation entry contact, the at least one charging entry contact being adapted to reduce a current flowing through the charging entry contact to enable charging of the drive cabinet plugin element, the at least one operation entry contact being adapted to allow a current to flow into the drive cabinet plugin element to be converted during operation;
at least one converted current connection element adapted to feed direct current converted into alternating current and/or three-phase current into the drive cabinet and to receive alternating current and/or three-phase current to be converted into direct current;
the at least one exit contact being adapted to allow a current converted from alternating current and/or three-phase current into direct current by the drive cabinet plugin element to leave the drive cabinet plugin element; and
at least one guiding element adapted to engage a guiding element counterpart of the drive cabinet, the guiding element fixing a vertical position of the drive cabinet plugin element inside the drive cabinet and enabling horizontal movement of the drive cabinet plugin element into and out of the drive cabinet, wherein such movement enabled by the guiding element provides a movement direction into and out of the drive cabinet, wherein based on the enabled movement, inwards and outwards locations are defined, and wherein the at least one charging entry contact is located inwards compared to the at least one operation entry contact.

16. The drive cabinet plugin element according to claim 1, wherein the at least two entry contacts are arranged above the at least one exit contact, based on an intended orientation of the drive cabinet plugin element in a drive cabinet.
